(19) United States
(12) Patent Application Publication
(10) Pub. No.: US 2025/0273627 A1
(43) Pub. Date: Aug. 28, 2025

(54) PACKAGE COMPRISING A BASE SUBSTRATE AND INTEGRATED DEVICES

(71) Applicant: QUALCOMM Incorporated, San Diego, CA (US)

(72) Inventors: Yangyang SUN, San Diego, CA (US); Dongming HE, San Diego, CA (US); Yue LI, San Diego, CA (US)

(21) Appl. No.: 18/590,688

(22) Filed: Feb. 28, 2024

(51) Int. Cl. H01L 25/065; H01L 21/56; H01L 23/00; H01L 23/31; H01L 23/498; H01L 23/538; H01L 23/64

(52) U.S. Cl. CPC H01L 25/0655; H01L 21/56; H01L 23/3121; H01L 23/49811; H01L 23/5383; H01L 23/5389; H01L 23/642; H01L 23/645; H01L 24/08; H01L 24/32; H01L 24/80; H01L 24/83; H01L 2224/08225; H01L 2224/32225; H01L 2224/80895; H01L 2224/80896; H01L 2224/83

(57) ABSTRACT

A package comprising a base substrate; a first integrated device coupled to the base substrate through a bonding material; a second integrated device coupled to the base substrate through the bonding material; a fill material coupled to the base substrate, the first integrated device and the second integrated device; and a metallization portion coupled to the first integrated device and the second integrated device.

### FIELD

Various features relate to devices with integrated devices.

### BACKGROUND

A package may include a substrate and integrated devices. These components are coupled together to provide a package that may perform various electrical functions. There is an ongoing need to provide better performing packages. There is also an ongoing need to reduce the overall size of the packages.

### SUMMARY

Various features relate to devices with integrated devices.

One example provides a package comprising a base substrate; a first integrated device coupled to the base substrate through a bonding material; a second integrated device coupled to the base substrate through the bonding material; a fill material coupled to the base substrate, the first integrated device and the second integrated device; and a metallization portion coupled to the first integrated device and the second integrated device.

Another example provides a method for fabricating a package. The method provides a base substrate. The method couples a first integrated device to the base substrate through a bonding material. The method couples a second integrated device to the base substrate through the bonding material. The method couples a fill material to the base substrate, the first integrated device and the second integrated device. The method couples a metallization portion to the first integrated device and the second integrated device.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes a base substrate, integrated devices and a metallization portion.

FIG. 2 illustrates an exemplary cross sectional profile view of a package that includes a base substrate, integrated devices and a metallization portion.

FIG. 3 illustrates an exemplary cross sectional profile view of a package that includes a base substrate, integrated devices and a metallization portion.

FIG. 4 illustrates an exemplary cross sectional profile view of an integrated device.

FIGS. 5A-5C illustrate an exemplary sequence for fabricating a package that includes a base substrate, integrated devices and a metallization portion.

FIG. 6 illustrates an exemplary flow chart of a method for fabricating a package that includes a base substrate, integrated devices and a metallization portion.

FIGS. 7A-7C illustrate an exemplary sequence for fabricating a metallization portion.

FIG. 8 illustrates an exemplary cross sectional profile view of a redistribution portion.

FIG. 9 illustrates an exemplary flow chart of a method for fabricating a metallization portion.

FIGS. 10A-10B illustrate an exemplary sequence for fabricating a metallization portion.

FIG. 11 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package comprising a base substrate; a first integrated device coupled to the base substrate through a bonding material; a second integrated device coupled to the base substrate through the bonding material; a fill material coupled to the base substrate, the first integrated device and the second integrated device; and a metallization portion coupled to the first integrated device and the second integrated device. The bonding material and/or the fill material may include one or more inorganic materials. As will be further described below, the package has a compact form factor while providing high density interconnections, improved thermal performance and/or improved performance.

### Exemplary Package Comprising a Base Substrate, Integrated Devices and a Metallization Portion

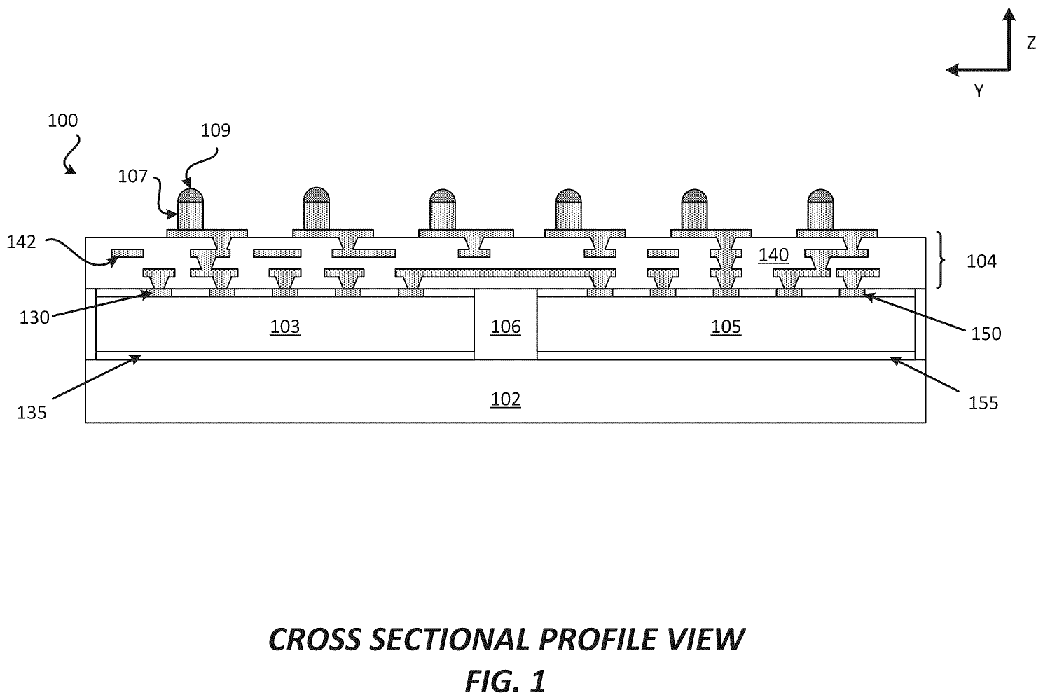

FIG. 1 illustrates a cross sectional profile view of a package 100 that includes a base substrate 102, an integrated device 103, an integrated device 105, a fill material 106, a metallization portion 104, a plurality of pillar interconnects 107, a plurality of solder interconnects 109, a bonding material 135 and a bonding material 155.

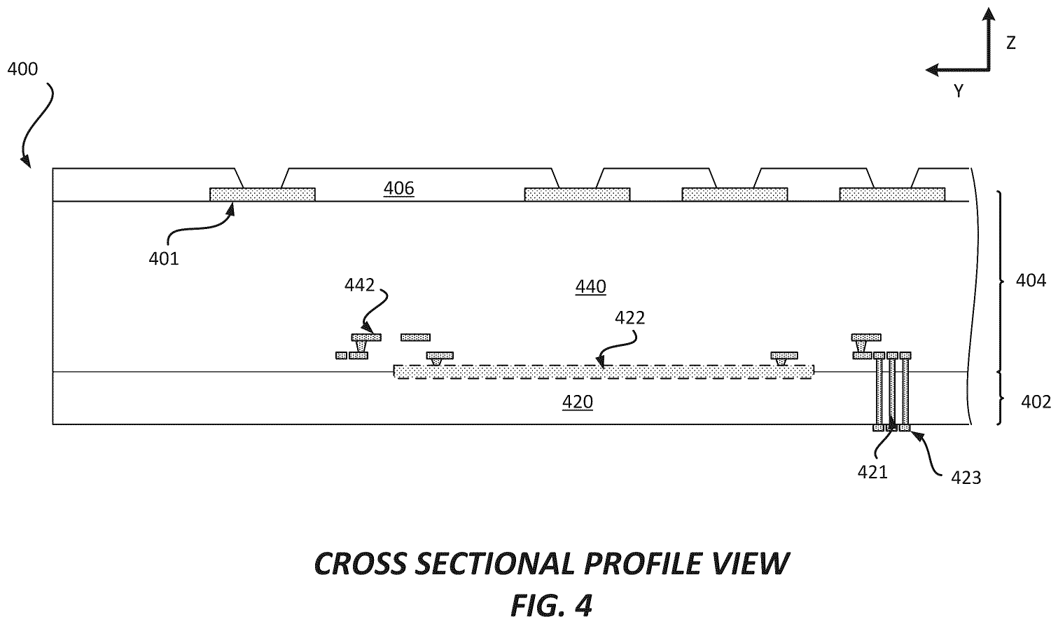

The base substrate 102 may include silicon (Si) (e.g., silicon wafer). The integrated device 103 includes a front side and a back side. The integrated device 103 comprises a plurality of pads 130. The front side of the integrated device 103 may include the side that comprises the plurality of pads 130. The back side of the integrated device 103 may include the side that comprises a die substrate. The integrated device 105 includes a front side and a back side. The integrated device 105 comprises a plurality of pads 150. The front side of the integrated device 105 may include the side that comprises the plurality of pads 150. The back side of the integrated device 105 may include the side that comprises a die substrate. A more detailed example of an integrated device is illustrated and described below in at least FIG. 4.

The integrated device 103 is coupled to the base substrate 102. The integrated device 103 may be coupled to the base substrate 102 through the bonding material 135. The back side of the integrated device 103 may be coupled to the base substrate 102 through the bonding material 135. The bonding material 135 may include oxide and/or silicon. The bonding material 135 may be coupled to and touch (i) the base substrate 102 and (ii) the back side of the integrated device 103. For example the bonding material 135 may be coupled to and touch the die substrate of the integrated device 103. The integrated device 103 may be a first integrated device. The bonding material 135 may be a first bonding material. The bonding material 135 may include an inorganic material. In some implementations, the thickness of the integrated device 103 may have a thickness in a range of about 10-50 micrometers (e.g., 10-20 micrometers).

The integrated device 105 is coupled to the base substrate 102. The integrated device 105 may be coupled to the base substrate 102 through the bonding material 155. The back side of the integrated device 105 may be coupled to the base substrate 102 through the bonding material 155. The bonding material 155 may include oxide and/or silicon. The bonding material 155 may be coupled to and touch (i) the base substrate 102 and (ii) the back side of the integrated device 105. For example the bonding material 155 may be coupled to and touch the die substrate of the integrated device 105. The integrated device 105 may be a second integrated device. The bonding material 155 may be a second bonding material. The bonding material 155 may include an inorganic material. In some implementations, the thickness of the integrated device 105 may have a thickness in a range of about 10-50 micrometers (e.g., 10-20 micrometers).

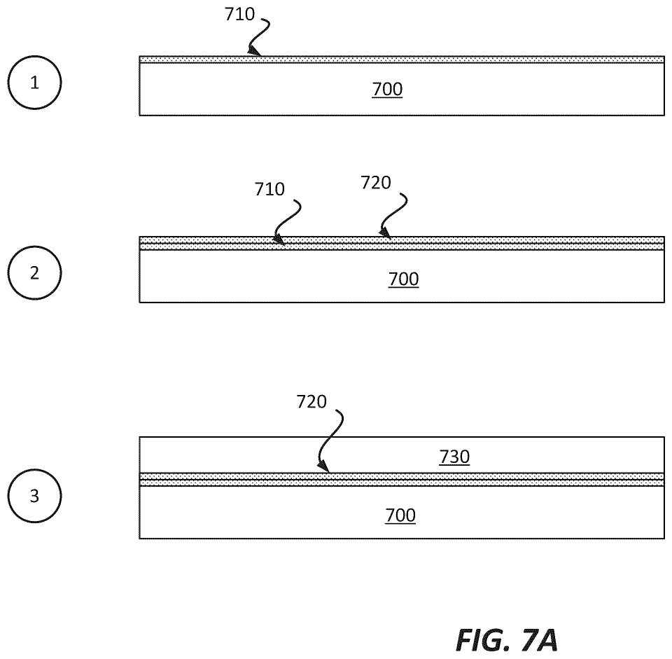

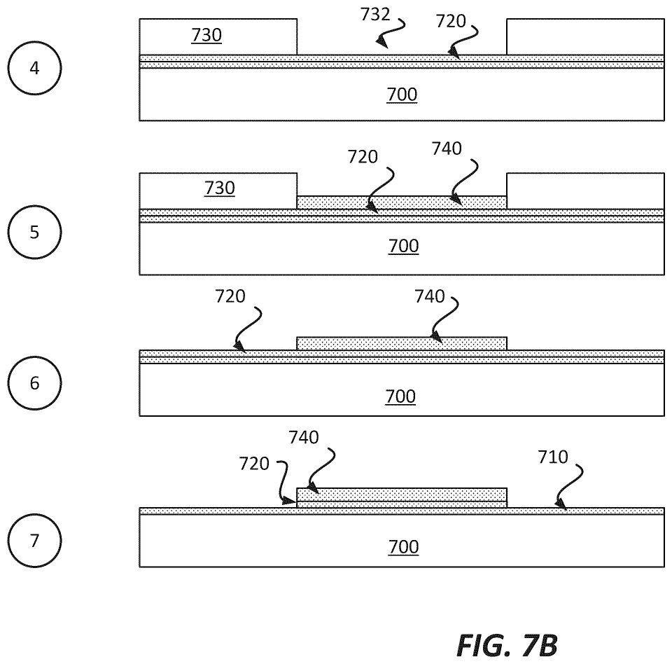

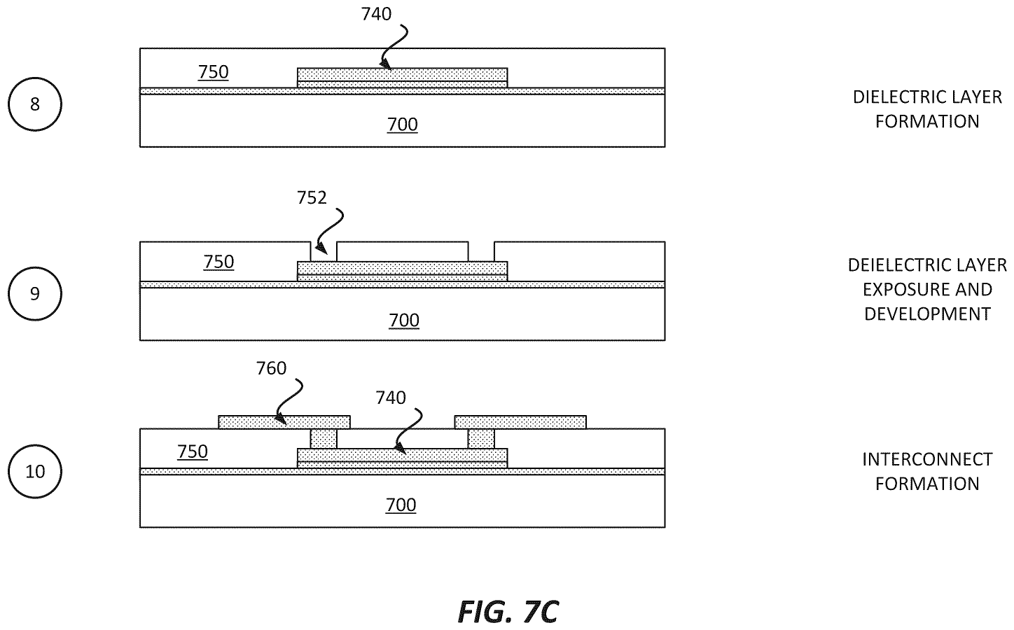

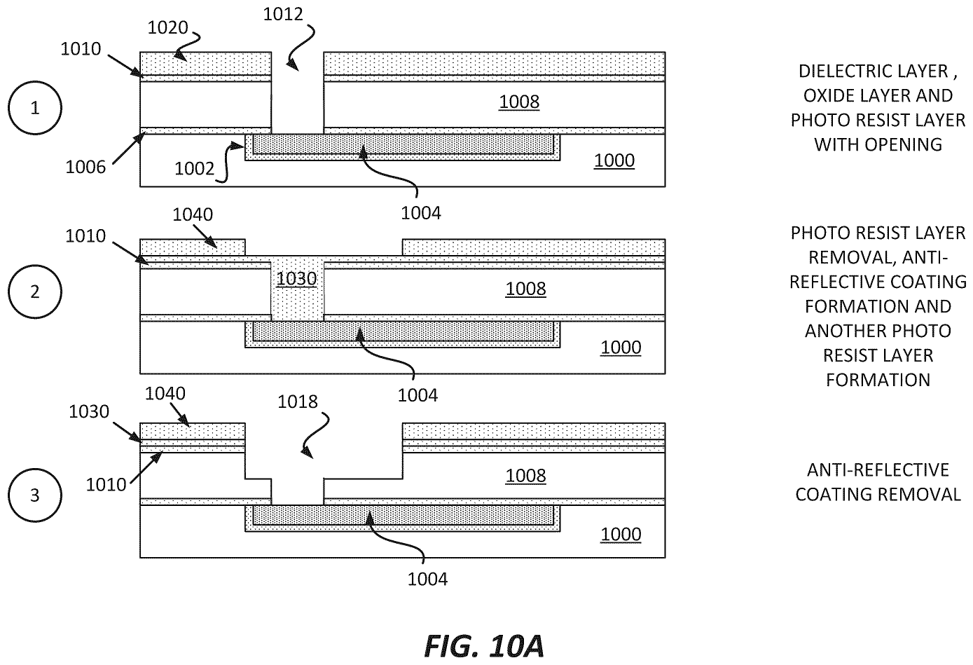

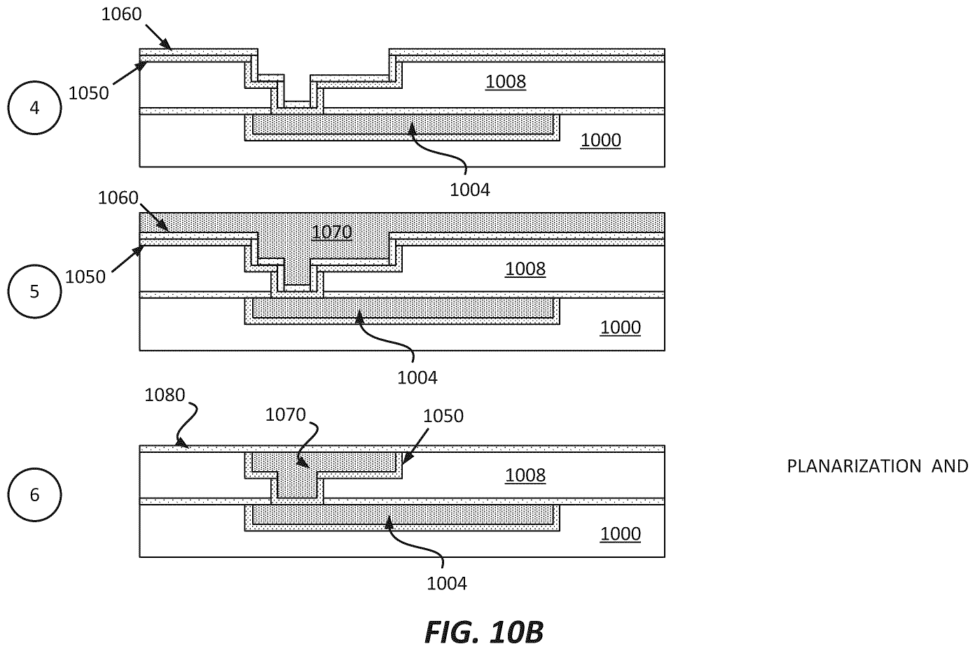

The metallization portion 104 includes a plurality of metallization interconnects 142 and at least one dielectric layer 140. The metallization portion 104 is coupled to the front side of the integrated device 103 and the front side of the integrated device 105. The plurality of metallization interconnects 142 may be coupled to and touch the plurality of pads 130 of the integrated device 103 and the plurality of pads 150 of the integrated device 105. The metallization portion 104 may include a redistribution portion that includes a plurality of redistribution interconnects. The plurality of metallization interconnects 142 may include a plurality of redistribution interconnects. The plurality of metallization interconnects 142 may include a plurality of damascene interconnects. In some implementations, the plurality of metallization interconnects 142 may comprise interconnects with width and/or spacing that are less than 1 micron. In some implementations, the plurality of metallization interconnects 142 may have a minimum pitch of about 25 nanometers (nm). Different processes may be used to form the metallization portion 104. Examples of processes for forming the metallization portion 104 are further described below in at least FIGS. 7A-7C and/or FIGS. 10A-10B.

The fill material 106 is located between the base substrate 102 and the metallization portion 104. The fill material 106 may be coupled to and touch the base substrate 102 and the metallization portion 104. The fill material 106 may at least partially encapsulate the integrated device 103 and the integrated device 105. The fill material 106 may at least laterally surround the integrated device 103. The fill material 106 may at least laterally surround the integrated device 105. The fill material 106 may touch a side surface of the integrated device 103 and/or a side surface of the integrated device 105. The fill material 106 may include an inorganic material. The fill material 106 may include silicon oxide. In some implementations, as used in the disclosure, silicon oxide may refer to SiOx, where x may be one or greater. For example, silicon oxide may also mean to include silicon dioxide. The fill material 106 may include the same material and/or similar materials as the bonding material 135 and/or the bonding material 155. The use of the fill material 106, the bonding material 135 and/or the bonding material 155 comprising an inorganic material, which has better thermal properties than an organic material, may help improve the performance of the integrated devices and/or the package by providing improved heat dissipation for the integrated devices and/or the package.

The fill material 106 may include an encapsulation layer, such as a mold, a resin and/or an epoxy. The fill material 106 may be a means for encapsulation. The fill material 106 may be provided by using a compression and transfer molding process, a sheet molding process, or a liquid molding process. An organic material may include polyimide, an underfill and/or a molding compound.

The plurality of pillar interconnects 107 are coupled to the metallization portion 104. The plurality of pillar interconnects 107 may be coupled to the plurality of metallization interconnects 142 The plurality of solder interconnects 109 are coupled to the plurality of pillar interconnects 107. The package 100 may be an integrated device package. In some implementations, the package 100 may be coupled to a board (e.g., printed circuit board) through the plurality of pillar interconnects 107 and the plurality of solder interconnects 109.

An electrical path between the integrated device 103 and the integrated device 105 may include a pad from the plurality of pads 130, at least one metallization interconnect from the plurality of metallization interconnects 142 and/or a pad from the plurality of pads 150.

An electrical path between the integrated device 103 and the plurality of solder interconnects 109 may include a pad from the plurality of pads 130, at least one metallization interconnects from the plurality of metallization interconnects 142, a pillar interconnect from the plurality of pillar interconnects 107 and/or a solder interconnect from the plurality of solder interconnects 109.

An electrical path between the integrated device 105 and the plurality of solder interconnects 109 may include a pad from the plurality of pads 150, at least one metallization interconnects from the plurality of metallization interconnects 142, a pillar interconnect from the plurality of pillar interconnects 107 and/or a solder interconnect from the plurality of solder interconnects 109.

Power to the integrated device 103 may be provided through the front side of the integrated device 103. Power to the integrated device 105 may be provided through the front side of the integrated device 105.

It is noted that in some implementations, the base substrate 102, the bonding material 135 and/or the bonding material 155 may be optional. Different implementations may have different thicknesses for the base substrate 102.

The package 100 provides several technical advantages. One, the package 100 provides improved thermal performance of the package, which helps improve the overall performance of the package 100. Two, the metallization portion 104 helps provide fine pitch integrated device to integrated device electrical connections, which can help improve the performance of the package 100. Three, providing power to the integrated device through the front side of the integrated device helps provide improved power delivery power, which may improve the performance of the package 100. Four, the structure and/or the configuration of the package may be fabricated using a more integrated fabrication process, which can help lower the cost of the package and/or improve the fabrication yield of the package. Five, the use of inorganic materials for the bonding material 135, the bonding material 155 and/or the fill material 106, helps provide improved thermal performance (e.g., improved heat dissipation), which may help improve the performance of the package.

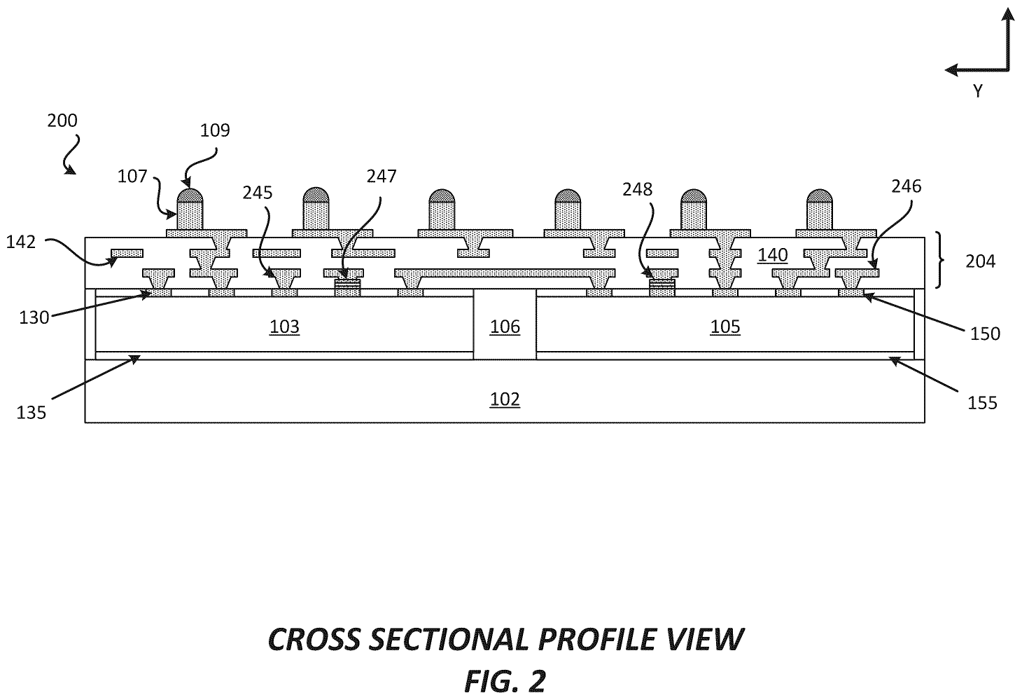

FIG. 2 illustrates a cross sectional profile view of a package 200 that includes a base substrate 102, an integrated device 103, an integrated device 105, a fill material 106, a metallization portion 204, a plurality of pillar interconnects 107, a plurality of solder interconnects 109, a bonding material 135 and a bonding material 155.

The package 200 of FIG. 2 is similar to the package 100 of FIG. 1, and may include components that are similar and/or arranged in a similar manner, as described for the package 100. The package 200 includes the metallization portion 204. The metallization portion 204 is similar to the metallization portion 104. However, the metallization portion 204 includes additional passive components and/or interconnects configured as passive components. The metallization portion 204 includes at least one dielectric layer 140, a plurality of metallization interconnects 142, a passive device 247 and a passive device 248. The plurality of metallization interconnects 142 include at least one metallization interconnect 245 and at least one metallization interconnect 246.

The passive device 247 may include a capacitor. The capacitor may include a metal-insulator-metal (MIM) capacitor. The passive device 248 may include a capacitor. The capacitor may include a metal-insulator-metal (MIM) capacitor. The at least one metallization interconnect 245 may be configured as an inductor. The at least one metallization interconnect 246 may be configured as an inductor.

The passive device 247 may be coupled to the integrated device 103. For example, the passive device 247 (e.g., capacitor) may be coupled to one or more pads from the plurality of pads 130 of the integrated device 103. The capacitor 248 may be coupled to the integrated device 105. For example, the capacitor 248 (e.g., capacitor) may be coupled to one or more pads from the plurality of pads 150 of the integrated device 105. The passive device 247 and/or the capacitor 248 may be considered part of the metallization portion 204. The passive device 247 and/or the capacitor 248 may be located in the metallization portion 204.

The metallization portion 204 is coupled to the front side of the integrated device 103 and the front side of the integrated device 105. The plurality of metallization interconnects 142 may be coupled to and touch the plurality of pads 130 of the integrated device 103 and the plurality of pads 150 of the integrated device 105. The metallization portion 204 may include a redistribution portion that includes a plurality of redistribution interconnects. The plurality of metallization interconnects 142 may include a plurality of redistribution interconnects. The plurality of metallization interconnects 142 may include a plurality of damascene interconnects. In some implementations, the plurality of metallization interconnects comprises interconnects with width and/or spacing that are less than 1 micron. In some implementations, the plurality of metallization interconnects comprises interconnects with minimum width and/or spacing of about 25 nanometers (nm). In some implementations, the plurality of metallization interconnects comprises interconnects with a minimum pitch of about 25 nanometers (nm).

The fill material 106 is located between the base substrate 102 and the metallization portion 204. The fill material 106 may touch the base substrate 102 and the metallization portion 204. The fill material 106 may at least partially encapsulate the integrated device 103 and the integrated device 105. The fill material 106 may at least laterally surround the integrated device 103. The fill material 106 may at least laterally surround the integrated device 105. The fill material 106 may touch a side surface of the integrated device 103 and/or a side surface of the integrated device 105. The fill material 106 include inorganic material. The fill material 106 may include silicon oxide. The fill material 106 may include an encapsulation layer, such as a mold, a resin and/or an epoxy. The fill material 106 may be a means for encapsulation. The fill material 106 may be provided by using a compression and transfer molding process, a sheet molding process, or a liquid molding process.

The integrated device 103 is coupled to the base substrate 102. The integrated device 103 may be coupled to the base substrate 102 through the bonding material 135. The back side of the integrated device 103 may be coupled to the base substrate 102 through the bonding material 135. The bonding material 135 may include oxide and/or silicon. The bonding material 135 may be coupled to and touch (i) the base substrate and (ii) the back side of the integrated device 103. For example the bonding material 135 may be coupled to and touch the die substrate of the integrated device 103. It is noted that in some implementations, the base substrate 102, the bonding material 135 and/or the bonding material 155 may be optional.

The integrated device 105 is coupled to the base substrate 102. The integrated device 105 may be coupled to the base substrate 102 through the bonding material 155. The back side of the integrated device 105 may be coupled to the base substrate 102 through the bonding material 155. The bonding material 155 may include oxide and/or silicon. The bonding material 155 may be coupled to and touch (i) the base substrate and (ii) the back side of the integrated device 105. For example the bonding material 155 may be coupled to and touch the die substrate of the integrated device 105.

An electrical path between the integrated device 103 and the plurality of solder interconnects 109 may include a pad from the plurality of pads 130, the passive device 247, at least one metallization interconnects from the plurality of metallization interconnects 142, a pillar interconnect from the plurality of pillar interconnects 107 and/or a solder interconnect from the plurality of solder interconnects 109.

An electrical path between the integrated device 103 and the plurality of solder interconnects 109 may include a pad from the plurality of pads 130, the at least one metallization interconnect 245 (e.g., configured as an inductor), at least one metallization interconnects from the plurality of metallization interconnects 142, a pillar interconnect from the plurality of pillar interconnects 107 and/or a solder interconnect from the plurality of solder interconnects 109.

An electrical path between the integrated device 103 and the plurality of solder interconnects 109 may include a pad from the plurality of pads 130, the at least one metallization interconnect 245 (e.g., configured as an inductor), the passive device 247, at least one metallization interconnects from the plurality of metallization interconnects 142, a pillar interconnect from the plurality of pillar interconnects 107 and/or a solder interconnect from the plurality of solder interconnects 109.

An electrical path between the integrated device 105 and the plurality of solder interconnects 109 may include a pad from the plurality of pads 150, the passive device 248, at least one metallization interconnects from the plurality of metallization interconnects 142, a pillar interconnect from the plurality of pillar interconnects 107 and/or a solder interconnect from the plurality of solder interconnects 109.

An electrical path between the integrated device 105 and the plurality of solder interconnects 109 may include a pad from the plurality of pads 150, the at least one metallization interconnect 246 (e.g., configured as an inductor), at least one metallization interconnects from the plurality of metallization interconnects 142, a pillar interconnect from the plurality of pillar interconnects 107 and/or a solder interconnect from the plurality of solder interconnects 109.

An electrical path between the integrated device 105 and the plurality of solder interconnects 109 may include a pad from the plurality of pads 150, the at least one metallization interconnect 246 (e.g., configured as an inductor), the passive device 248, at least one metallization interconnects from the plurality of metallization interconnects 142, a pillar interconnect from the plurality of pillar interconnects 107 and/or a solder interconnect from the plurality of solder interconnects 109.

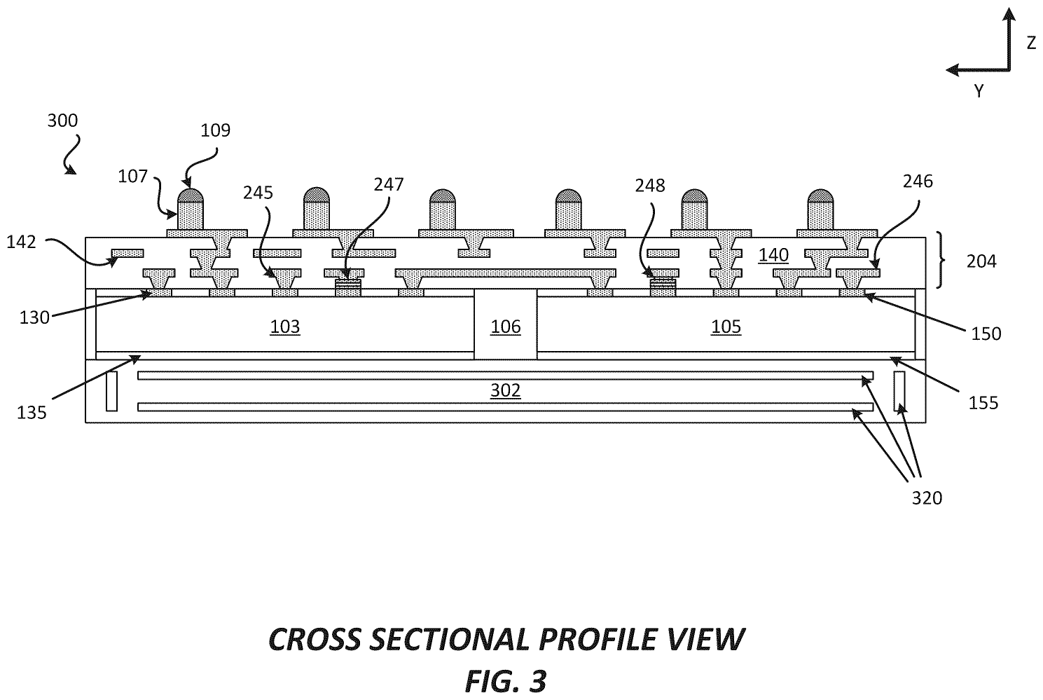

FIG. 3 illustrates a cross sectional profile view of a package 300 that includes a base substrate 302, an integrated device 103, an integrated device 105, a fill material 106, a metallization portion 204, a plurality of pillar interconnects 107, a plurality of solder interconnects 109, a bonding material 135 and a bonding material 155.

The package 300 of FIG. 3 is similar to the package 100 of FIG. 1 and/or the package 200 of FIG. 2, and may include components that are similar and/or arranged in a similar manner, as described for the package 100 and/or the package 200.

The base substrate 302 is similar to the base substrate 102. The base substrate 302 may include silicon (Si). The base substrate 302 includes a plurality of cavities 320. The plurality of cavities 320 may be hollow or may be filled with a material (e.g., gas, liquid). The plurality of cavities 320 may be configured as channels for storing fluids. The use of the plurality of cavities 320 may help improve the thermal performance of the package 300.

The integrated device 103 is coupled to the base substrate 302. The integrated device 103 may be coupled to the base substrate 302 through the bonding material 135. The back side of the integrated device 103 may be coupled to the base substrate 302 through the bonding material 135. The bonding material 135 may include oxide and/or silicon. The bonding material 135 may be coupled to and touch (i) the base substrate 302 and (ii) the back side of the integrated device 103. For example the bonding material 135 may be coupled to and touch the die substrate of the integrated device 103.

The integrated device 105 is coupled to the base substrate 302. The integrated device 105 may be coupled to the base substrate 302 through the bonding material 155. The back side of the integrated device 105 may be coupled to the base substrate 302 through the bonding material 155. The bonding material 155 may include oxide and/or silicon. The bonding material 155 may be coupled to and touch (i) the base substrate 302 and (ii) the back side of the integrated device 105. For example the bonding material 155 may be coupled to and touch the die substrate of the integrated device 105. It is noted that in some implementations, the base substrate 302, the bonding material 135 and/or the bonding material 155 may be optional.

The fill material 106 is located between the base substrate 302 and the metallization portion 104. The fill material 106 may touch the base substrate 302 and the metallization portion 104. The fill material 106 may at least partially encapsulate the integrated device 103 and the integrated device 105. The fill material 106 may at least laterally surround the integrated device 103. The fill material 106 may at least laterally surround the integrated device 105. The fill material 106 may touch a side surface of the integrated device 103 and/or a side surface of the integrated device 105. The fill material 106 include inorganic material. The fill material 106 may include silicon oxide. The fill material 106 may include an encapsulation layer, such as a mold, a resin and/or an epoxy. The fill material 106 may be a means for encapsulation. The fill material 106 may be provided by using a compression and transfer molding process, a sheet molding process, or a liquid molding process.

### Exemplary Integrated Device

FIG. 4 illustrates a cross sectional profile view of an integrated device 400 that includes a die substrate. The integrated device 400 may represent the integrated device 103 and/or the integrated device 105. The integrated device 400 includes a die substrate portion 402 and a die interconnection portion 404. The die substrate portion 402 includes a die substrate 420, an active region 422 and a plurality of through substrate vias 421. The active region 422 may include a plurality of logic cells, a plurality of transistors, and/or a plurality of filters. Different implementations may use different types of transistors, such as a field effect transistor (FET), planar FET, finFET, and a gate all around FET. In some implementations, a front end of line (FEOL) process may be used to fabricate the active region 422 of the die substrate 420.

The die substrate 420 may include silicon (Si). The die substrate 420 may comprise a bulk silicon. The bulk silicon may include a monolith silicon. The plurality of through substrate vias 421 may extend through the die substrate 420. Different implementations may have different thicknesses for the die substrate 420. In some implementations, the integrated device 400 may include a back side metallization portion that is coupled to the die substrate 420. The back side metallization portion may include a plurality of back side metallization interconnects that are coupled to the plurality of through substrate vias 421.

The die interconnection portion 404 includes at least one dielectric layer 440 and a plurality of die interconnects 442. The die interconnection portion 404 is coupled to the die substrate portion 402. The plurality of die interconnects 442 is coupled to the active region 422 of the die substrate portion 402. The die interconnection portion 404 may also include a plurality of pad interconnects 401 and a passivation layer 406. In some implementations, a back end of line (BEOL) process may be used to fabricate the die interconnection portion 404. In some implementations, the process shown in FIGS. 10A-10B may be used to fabricate the die interconnection portion 404, including forming the at least one dielectric layer 440 and the plurality of die interconnects 442. A plurality of metallization interconnects 423 may be coupled to the plurality of through substrate vias 421. The plurality of metallization interconnects 423 may be part of a back side metallization portion that is formed and coupled to back side of the die substrate 420.

In some implementations, an electrical path to and/or from an active region 422 may include at least one die interconnect from the plurality of die interconnects 442, at least one through substrate via from the plurality of through substrate vias 421. In some implementations, an electrical path to and/or from an active region 422 may include at least one die interconnect from the plurality of die interconnects 442, at least one pad interconnect from the plurality of pad interconnects 401. The integrated device 400 includes a front side and a back side. The front side of the integrated device 400 may be the side that includes the plurality of pad interconnects 401. The back side of the integrated device 400 may be the side that includes the die substrate 420, the through substrate vias 421 and/or the plurality of metallization interconnects 423.

An integrated device (e.g., 103, 105) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100, 200, 300) may be implemented in a radio frequency (RF) package. The RF package may be a radio frequency front end (RFFE) package. A package (e.g., 100, 200, 300) may be configured to provide Wireless Fidelity (WiFi) communication and/or cellular communication (e.g., 2G, 3G, 4G, 5G). The packages (e.g., 100, 200, 300) may be configured to support Global System for Mobile (GSM) Communications, Universal Mobile Telecommunications System (UMTS), and/or Long-Term Evolution (LTE). The packages (e.g., 100, 200, 300) may be configured to transmit and receive signals having different frequencies and/or communication protocols.

### Exemplary Sequence for Fabricating a Package Comprising a Base Substrate, Integrated Devices and a Metallization Portion

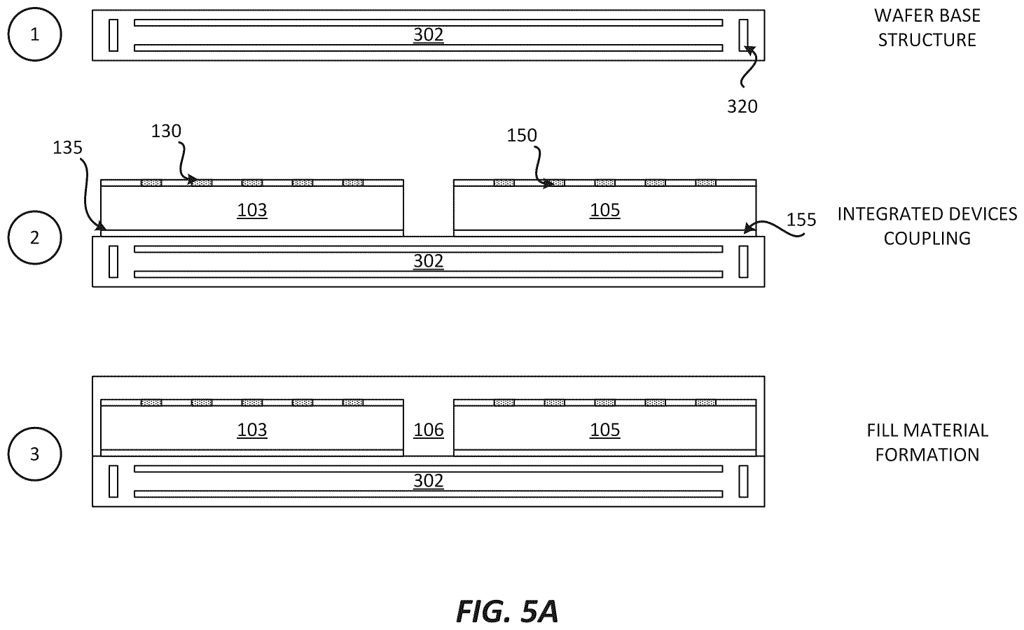

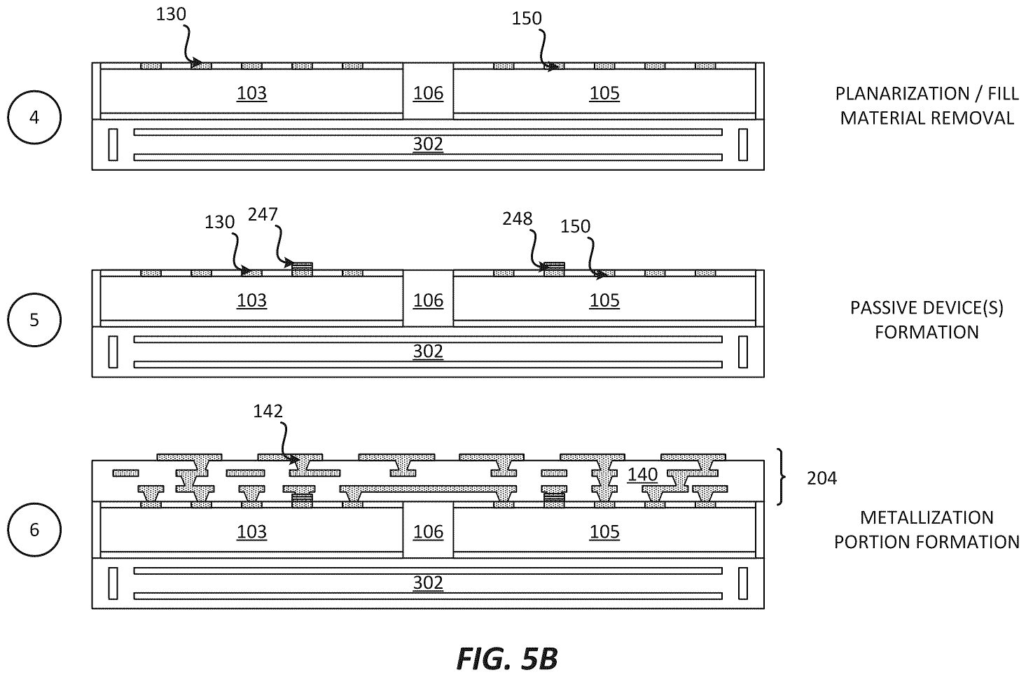

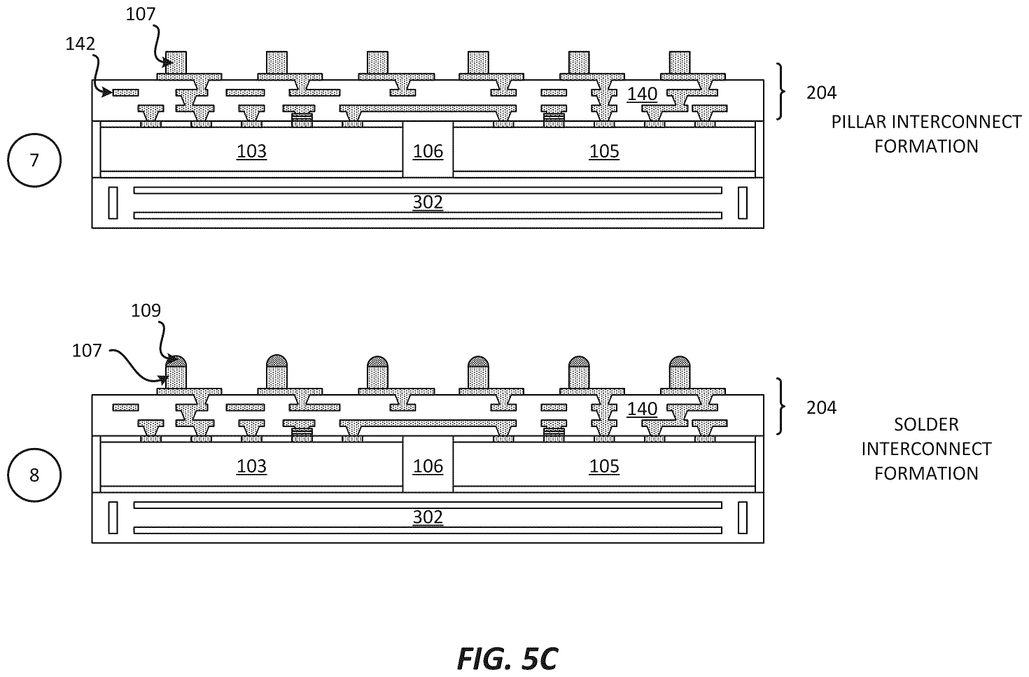

In some implementations, fabricating a package includes several processes. FIGS. 5A-5C illustrate an exemplary sequence for providing or fabricating a package. In some implementations, the sequence of FIGS. 5A-5C may be used to provide or fabricate the package 300.

It should be noted that the sequence of FIGS. 5A-5C may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.
Stage 1, as shown in FIG. 5A, illustrates a state after a base substrate 302 is provided. The base substrate 302 may include silicon (Si). The base substrate 302 may include a plurality of cavities 320. The plurality of cavities 320 may be configured as channels for storing fluid and/or for a fluid to pass through. The plurality of cavities 320 may be hollow or filled with a gas material, a solid material and/or a liquid material.
Stage 2 illustrates a state after the integrated device 103 and the integrated device 105 are coupled to the base substrate 302. The back side of the integrated device 103 may be coupled to the base substrate 302 through a bonding material 135. The bonding material 135 may be located between the base substrate 302 and the integrated device 103. The bonding material 135 may be a first bonding material. The back side of the integrated device 105 may be coupled to the base substrate 302 through a bonding material 155. The bonding material 155 may be located between the base substrate 302 and the integrated device 105. The bonding material 155 may be a second bonding material. The bonding material 135 and the bonding material 155 may include the same bonding material. The bonding material 135 and the bonding material 155 may be considered part of the same bonding material. The bonding material 135 and the bonding material 155 may be considered as separate bonding materials. The bonding material 135 and/or the bonding material 155 may include an inorganic material (e.g., silicon oxide, silicon oxide layer).
Stage 3 illustrates a state after a fill material 106 is provided and formed. The fill material 106 may be coupled to and touch the base substrate 302, the integrated device 103 and the integrated device 105. The fill material 106 includes inorganic material. The fill material 106 may include silicon oxide (e.g., silicon oxide layer). In some implementations, the fill material 106 may include the same material (e.g., same inorganic material) as the bonding material 135 and/or the bonding material 155. In some implementations, the fill material 106 may include a different material (e.g., a different inorganic material) as the bonding material 135 and/or the bonding material 155.

In some implementations, the fill material 106 may include an organic material. In some implementations, the fill material 106 may include an encapsulation layer, such as a mold, a resin and/or an epoxy. The fill material 106 may be a means for encapsulation. The fill material 106 may be provided by using a compression and transfer molding process, a sheet molding process, or a liquid molding process.
Stage 4, as shown in FIG. 5B, illustrates a state after portions of the fill material 106 are removed. The fill material 106 may be grinded and/or polished. In some implementations, portions of the integrated device 103 and/or portions of the integrated device 105 may also be removed. For example, portions of the front side of the integrated device 103 and/or portions of the front side of the integrated device 105 may be removed. A planarization process may be used to remove portions of the fill material 106.
Stage 5 illustrates a state after a passive device 247 and a passive device 248 are formed. The passive device 247 may be formed and coupled to the integrated device 103. For example, the passive device 247 may be formed and coupled to at least one pad from the plurality of pads 130 of the integrated device 103. A plating process, a deposition process, a lamination process, a lithography process, strip process, an etching process, an exposure process and/or a development process may be used to form the passive device 247. The passive device 247 may include a metal-insulator-metal (MIM) capacitor. The passive device 248 may be formed and coupled to the integrated device 105. For example, the passive device 248 may be formed and coupled to at least one pad from the plurality of pads 150 of the integrated device 105. A plating process, a deposition process, a lamination process, a lithography process, strip process, an etching process, an exposure process and/or a development process may be used to form the passive device 248. The passive device 248 may include a metal-insulator-metal (MIM) capacitor.
Stage 6 illustrates a state after a metallization portion 104 is formed and coupled to the integrated device 103, the integrated device 105 and the fill material 106. The metallization portion 104 may include at least one dielectric layer 140 and a plurality of metallization interconnects 142. The metallization portion 104 may be formed such that the passive device 247 and/or the passive device 248 are located at least partially in the metallization portion 104. In some implementations, the metallization portion 104 may include at least one interconnect that is configured as an inductor, such as the metallization interconnect 245 and/or the metallization interconnect 246. The metallization portion 104 may include a redistribution portion that includes a plurality of redistribution interconnects. FIGS. 7A-7C illustrate an example of a process for fabricating a metallization portion and/or redistribution portion. FIGS. 10A-10B illustrate another example of a process for fabricating a metallization portion, where the metallization portion includes damascene interconnects.
Stage 7, as shown in FIG. 5C, illustrates a state after the plurality of pillar interconnects 107 are formed and coupled to the metallization portion 104. The plurality of pillar interconnects 107 are coupled to the plurality of metallization interconnects 142. A lithography process, a plating process, a strip process and/or an etching process may be used to form the plurality of pillar interconnects 107.
Stage 8 illustrates a state after a plurality of solder interconnects 109 are coupled to the plurality of pillar interconnects 107. A solder reflow process may be used to form and couple the plurality of solder interconnects 109 to the plurality of pillar interconnects 107. Stage 8 may illustrate the package 300 of FIG. 3.

### Exemplary Flow Diagram of a Method for Fabricating a Package Comprising a Base Substrate, Integrated Devices and a Metallization Portion

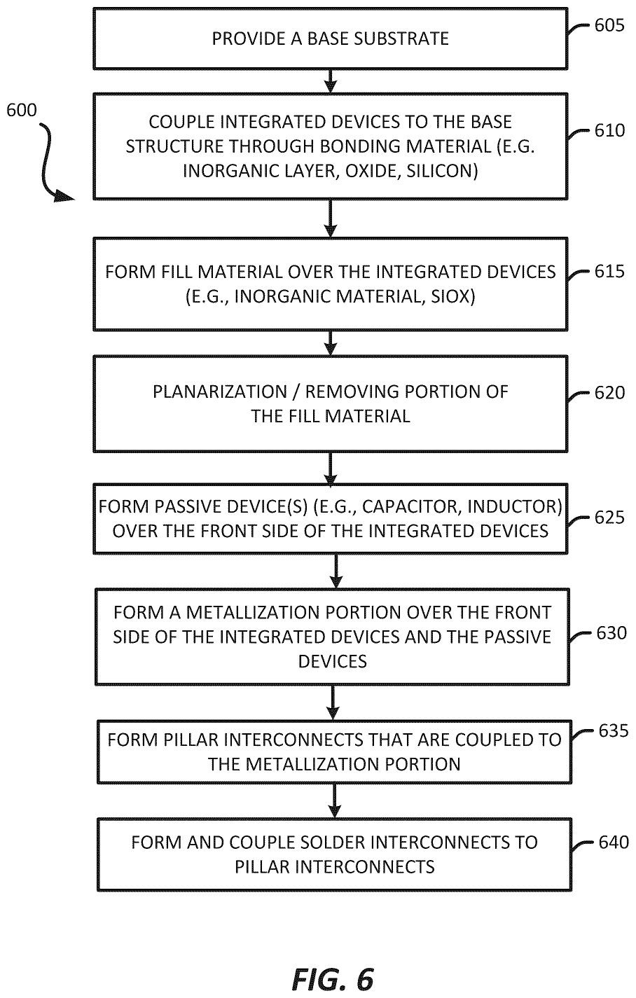

In some implementations, fabricating a package includes several processes. FIG. 6 illustrates an exemplary flow diagram of a method 600 for providing or fabricating a package. In some implementations, the method 600 of FIG. 6 may be used to provide or fabricate the package 300 described in the disclosure. However, the method 600 may be used to provide or fabricate any of the packages (e.g., 100, 200) described in the disclosure.

It should be noted that the method 600 of FIG. 6 may combine one or more processes in order to simplify and/or clarify the method for providing or fabricating a package. In some implementations, the order of the processes may be changed or modified.

The method provides (at 605) a base substrate. Stage 1 of FIG. 5A, illustrates and describes an example of a state after a base substrate 302 is provided. The base substrate 302 may include silicon (Si). The base substrate 302 may include a plurality of cavities 320. The plurality of cavities 320 may be configured as channels for storing fluid. The plurality of cavities 320 may be hollow or filled with a solid material and/or liquid material.

The method couples (a 610) integrated devices to the base substrate through a bonding material. Stage 2 of FIG. 5A, illustrates and describes an example of a state after the integrated device 103 and the integrated device 105 are coupled to the base substrate 302. The back side of the integrated device 103 may be coupled to the base substrate 302 through a bonding material 135. The bonding material 135 may be located between the base substrate 302 and the integrated device 103. The bonding material 135 may be a first bonding material. The back side of the integrated device 105 may be coupled to the base substrate 302 through a bonding material 155. The bonding material 155 may be located between the base substrate 302 and the integrated device 105. The bonding material 155 may be a second bonding material. The bonding material 135 and the bonding material 155 may include the same bonding material. The bonding material 135 and/or the bonding material 155 may include an inorganic material (e.g., silicon oxide, silicon oxide layer).

The method provides and forms (at 615) a fill material. Stage 3 of FIG. 5A, illustrates and describes an example of a state after a fill material 106 is provided and formed. The fill material 106 may be coupled to and touch the base substrate 302, the integrated device 103 and the integrated device 105. The fill material 106 includes inorganic material. The fill material 106 may include silicon oxide (e.g., silicon oxide layer). The fill material 106 may include an encapsulation layer, such as a mold, a resin and/or an epoxy. The fill material 106 may be a means for encapsulation. The fill material 106 may be provided by using a compression and transfer molding process, a sheet molding process, or a liquid molding process. An organic material may include polyimide, an underfill and/or a molding compound.

The method removes (at 620) a portion of the fill material. Stage 4 of FIG. 5B, illustrates and describes an example of a state after portions of the fill material 106 are removed. The fill material 106 may be grinded and/or polished. In some implementations, portions of the integrated device 103 and/or portions of the integrated device 105 may also be removed. For example, portions of the front side of the integrated device 103 and/or portions of the front side of the integrated device 105 may be removed.

The method forms (at 625) one or more passive devices and/or passive components. Stage 5 of FIG. 5C, illustrates and describes an example of a state after a passive device 247 and a passive device 248 are formed. The passive device 247 may be formed and coupled to the integrated device 103. For example, the passive device 247 may be formed and coupled to at least one pad from the plurality of pads 130 of the integrated device 103. A plating process, a deposition process, a lamination process, a lithography process, strip process, an etching process, an exposure process and/or a development process may be used to form the passive device 247. The passive device 247 may include a metal-insulator-metal (MIM) capacitor. The passive device 248 may be formed and coupled to the integrated device 105. For example, the passive device 248 may be formed and coupled to at least one pad from the plurality of pads 150 of the integrated device 105. A plating process, a deposition process, a lamination process, a lithography process, strip process, an etching process, an exposure process and/or a development process may be used to form the passive device 248. The passive device 248 may include a metal-insulator-metal (MIM) capacitor.

The method forms and couples (at 630) a metallization portion to the fill material and the integrated devices. Stage 6 of FIG. 5C, illustrates a state after a metallization portion 104 is formed and coupled to the integrated device 103, the integrated device 105 and the fill material 106. The metallization portion 104 may include at least one dielectric layer 140 and a plurality of metallization interconnects 142. The metallization portion 104 may be formed such that the passive device 247 and/or the passive device 248 are located at least partially in the metallization portion 104. In some implementations, the metallization portion 104 may include at least one interconnect that is configured as an inductor, such as the metallization interconnect 245 and/or the metallization interconnect 246. The metallization portion 104 may include a redistribution portion that includes a plurality of redistribution interconnects. FIGS. 7A-7C illustrate an example of a process for fabricating a metallization portion and/or redistribution portion. FIGS. 10A-10B illustrate another example of a process for fabricating a metallization portion, where the metallization portion includes damascene interconnects.

The method forms and couples (at 635) a plurality of pillar interconnects to the metallization portion. Stage 7 of FIG. 5C, illustrates and describes an example of a state after the plurality of pillar interconnects 107 are formed and coupled to the metallization portion 104. The plurality of pillar interconnects 107 are coupled to the plurality of metallization interconnects 142. A lithography process, a plating process, a strip process and/or an etching process may be used to form the plurality of pillar interconnects 107.

The method forms and couples (at 640) a plurality of solder interconnects to the plurality of pillar interconnects. Stage 8 of FIG. 5C, illustrates and describes an example of a state after a plurality of solder interconnects 109 are coupled to the plurality of pillar interconnects 107. A solder reflow process may be used to form and couple the plurality of solder interconnects 109 to the plurality of pillar interconnects 107. Stage 8 may illustrate the package 300 of FIG. 3.

### Exemplary Sequence for Fabricating a Metallization Portion

In some implementations, fabricating a metallization portion includes several processes. FIGS. 7A-7C illustrate an exemplary sequence for providing or fabricating a metallization portion. In some implementations, the sequence of FIGS. 7A-7C may be used to provide or fabricate the metallization portion 104. However, the sequence of FIGS. 7A-7C may be used to form any of the metallization portions of the disclosure.

It should be noted that the sequence of FIGS. 7A-7C may combine one or more stages in order to simplify and/or clarify the sequence for providing or fabricating a metallization portion. In some implementations, the order of the processes may be changed or modified. In some implementations, one or more of processes may be replaced or substituted without departing from the scope of the disclosure.
Stage 1, as shown in FIG. 7A, illustrates a state after a substrate 700 and a silicon oxide layer 710 are provided. The substrate 700 may include a silicon substrate. The silicon oxide layer 710 may be include silicon dioxide (SiO₂).
Stage 2 illustrates a state after a seed layer 720 is formed and coupled to the silicon oxide layer 710. The seed layer 720 may include copper. The seed layer 720 may be disposed over the silicon oxide layer 710.
Stage 3 illustrates a state after a photo resist layer 730 is formed and coupled to the seed layer 720. A deposition process and/or a lamination process may be used to form the photo resist layer 730.
Stage 4, as shown in FIG. 7B, illustrates a state after a plurality of openings 732 are formed in the photo resist layer 730. The plurality of openings 732 may expose portions of the seed layer 720. An exposure process and/or a development process may be used to form the plurality of openings 732.
Stage 5 illustrates a state after a plurality of interconnects 740 are formed. The plurality of interconnects 740 may be formed in the plurality of openings 732 of the photo resist layer 730. The plurality of interconnects 740 may be coupled to the seed layer 720. A plating process may be used to form the plurality of interconnects 740.
Stage 6 illustrates a state after the photo resist layer 730 is removed. A resist strip process may be used to remove the photo resist layer 730.
Stage 7 illustrates a state after portions of the seed layer 720 are removed. An etching process may be used to remove portions of the seed layer 720. In some implementations, portions of the seed layer 720 that are not covered by the plurality of interconnects 740 may be removed.
Stage 8, as shown in FIG. 7C, illustrates a state after a dielectric layer 750 is formed over the silicon oxide layer 710 and/or over the plurality of interconnects 740. A deposition process and/or a lamination process may be used to form the dielectric layer 750 over the silicon oxide layer 710 and/or the plurality of interconnects 740.
Stage 9 illustrates a state after a plurality of openings 752 are formed in the dielectric layer 750. The plurality of openings 752 may expose portions of the plurality of interconnects 740. An exposure process and/or a development process may be used to form the plurality of openings 752.
Stage 10 illustrates a state after a plurality of interconnects 760 are formed. The plurality of interconnects 760 may be coupled to the plurality of interconnects 740. The plurality of interconnects 760 may be located in the plurality of openings 752 of the dielectric layer 750. The plurality of interconnects 760 may be located over a surface of the dielectric layer 750. A lithography process, a plating process, a strip process and/or an etching process may be used to form the plurality of interconnects 760.

In some implementations, the steps shown in stage 8 through stage 10 may be iteratively performed to form additional dielectric layers and/or additional plurality of interconnects for a metallization portion that includes several metal layers. The plurality of interconnects 740 and/or the plurality of interconnects 760 may include a plurality of metallization interconnects. In some implementations, instead of being formed over the substrate 700 and/or the silicon oxide layer 710, the plurality of interconnects may be formed over a fill material and/or one or more integrated devices.

In some implementations, a plurality of metallization interconnects for a metallization portion that are fabricated using the process of FIGS. 7A-7C may have a minimum width in a range of about 2-10 micrometers. In some implementations, a plurality of metallization interconnects for a metallization portion that are fabricated using the process of FIGS. 7A-7C may have a minimum space (e.g., minimum spacing) in a range of about 2-10 micrometers.

Different implementations may have metallization portions with metallization interconnects with different shapes.

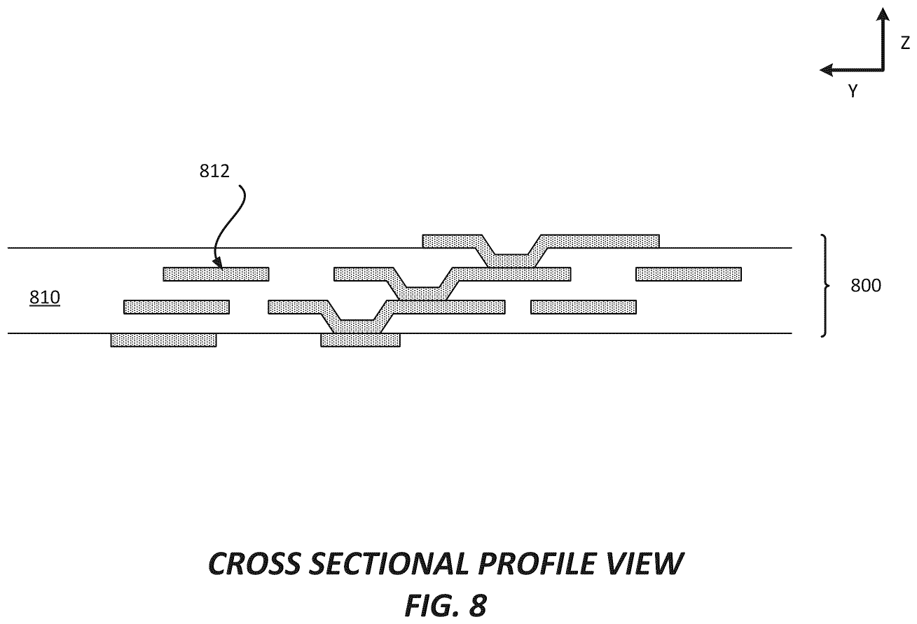

FIG. 8 illustrates a metallization portion 800 that includes at least one dielectric layer 810 and a plurality of metallization interconnects 812. The plurality of metallization interconnects 812 may include metallization interconnects with different shapes than those shown in FIGS. 1-3 of the disclosure. The metallization portion 800 may include a redistribution portion. The plurality of metallization interconnects 812 may include a plurality of redistribution interconnects. In some implementations, the metallization portion 800 may replace the metallization portion 104. The plurality of metallization interconnects 812 may replace the plurality of metallization interconnects 142. The metallization portion 800 may include metallization interconnects that have different shapes than the metallization interconnects of the metallization portion 104. In some implementations, the metallization portion 800 may be fabricated using a process that is the same and/or similar to the process of FIGS. 7A-7C.

### Exemplary Flow Diagram of a Method for Fabricating a Metallization Portion

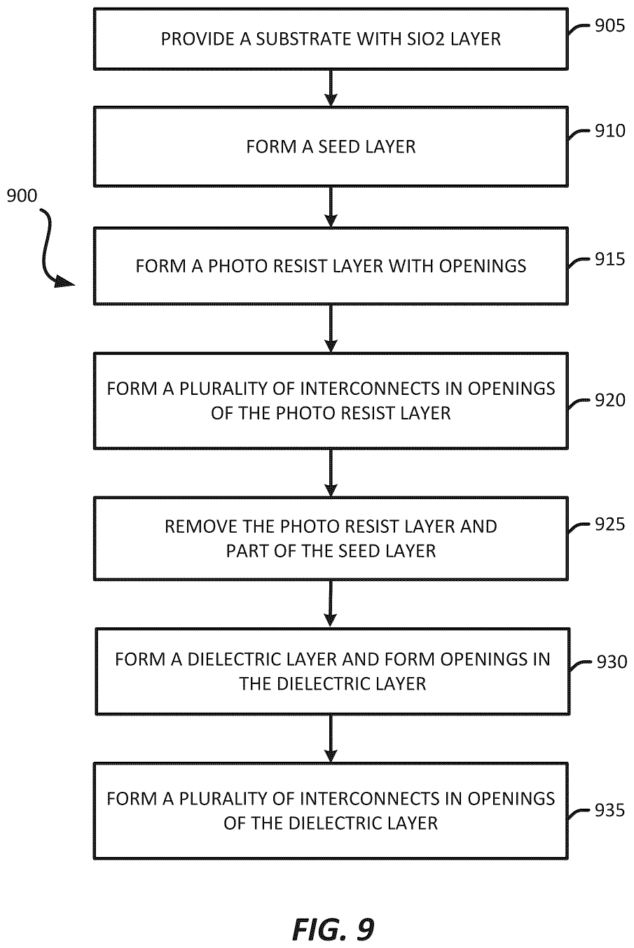

In some implementations, fabricating a metallization portion includes several processes. FIG. 9 illustrates an exemplary flow diagram of a method 900 for providing or fabricating a metallization portion. In some implementations, the method 900 of FIG. 9 may be used to provide or fabricate the metallization portion 104 described in the disclosure. However, the method 900 may be used to provide or fabricate any of the metallization portions (e.g., 800) described in the disclosure.

It should be noted that the method 900 of FIG. 9 may combine one or more processes in order to simplify and/or clarify the method for providing or fabricating a metallization portion. In some implementations, the order of the processes may be changed or modified.

The method provides (at 905) a substrate and a silicon oxide layer. Stage 1 of FIG. 7A, illustrates and describes an example of a state after a substrate 700 and a silicon oxide layer 710 is provided. The substrate 700 may include a silicon substrate. The silicon oxide layer 710 may be include silicon dioxide (SiO₂).

The method forms (at 910) a seed layer. Stage 2 of FIG. 7A, illustrates and describes an example of a state after a seed layer 720 is formed and coupled to the silicon oxide layer 710. The seed layer 720 may include copper. The seed layer 720 may be disposed over the silicon oxide layer 710.

The method forms (at 915) a photo resist layer with openings. Stage 3 of FIG. 7A, illustrates and describes an example of a state after a photo resist layer 730 is formed and coupled to the seed layer 720. A deposition process and/or a lamination process may be used to form the photo resist layer 730. Stage 4 of FIG. 7B, illustrates and describes an example of a state after a plurality of openings 732 are formed in the photo resist layer 730. The plurality of openings 732 may expose portions of the seed layer 720. An exposure process and/or a development process may be used to form the plurality of openings 732.

The method forms (at 920) a plurality of interconnects. Stage 5 of FIG. 7B, illustrates and describes an example of a state after a plurality of interconnects 740 are formed. The plurality of interconnects 740 may be formed in the plurality of openings 732 of the photo resist layer 730. The plurality of interconnects 740 may be coupled to the seed layer 720. A plating process may be used to form the plurality of interconnects 740.

The method removes (at 925) the photo resist layer and part of the seed layer. Stage 6 of FIG. 7B, illustrates and describes an example of a state after the photo resist layer 730 is removed. A resist strip process may be used to remove the photo resist layer 730. Stage 7 of FIG. 7B, illustrates and describes an example of a state after portions of the seed layer 720 are removing. An etching process may be used to remove portions of the seed layer 720. In some implementations, portions of the seed layer 720 that are not covered by the plurality of interconnects 740 may be removed.

The method forms (at 930) a dielectric layer with openings. Stage 8 of FIG. 7C, illustrates and describes an example of a state after a dielectric layer 750 is formed over the silicon oxide layer 710 and/or over the plurality of interconnects 740. A deposition process and/or a lamination process may be used to form the dielectric layer 750 over the silicon oxide layer 710 and/or the plurality of interconnects 740.

Stage 9 of FIG. 7C, illustrates and describes an example of a state after a plurality of openings 752 are formed in the dielectric layer 750. The plurality of openings 752 may expose portions of the plurality of interconnects 740. An exposure process and/or a development process may be used to form the plurality of openings 752.

The method forms (at 935) a plurality of interconnects. Stage 10 of FIG. 7C, illustrates and describes an example of a state after a plurality of interconnects 760 are formed. The plurality of interconnects 760 may be coupled to the plurality of interconnects 740. The plurality of interconnects 760 may be located in the plurality of openings 752 of the dielectric layer 750. The plurality of interconnects 760 may be located over a surface of the dielectric layer 750. A lithography process, a plating process, a strip process and/or an etching process may be used to form the plurality of interconnects 760.

In some implementations, forming (at 930) dielectric layers with openings and forming (at 935) a plurality of interconnects may be iteratively performed to form additional dielectric layers and/or additional plurality of interconnects for a metallization portion that includes several metal layers. The plurality of interconnects 740 and/or the plurality of interconnects 760 may include a plurality of metallization interconnects. In some implementations, instead of being formed over the substrate 700 and/or the silicon oxide layer 710, the plurality of interconnects may be formed over a fill material and/or one or more integrated devices.

### Exemplary Sequence for Fabricating a Metallization Portion

In some implementations, fabricating a metallization portion includes several processes. FIGS. 10A-10B illustrate an exemplary sequence for providing or fabricating a metallization portion. In some implementations, the sequence of FIGS. 10A-10B may be used to provide or fabricate the metallization portion 104. The metallization portion 104 may be fabricated using a damascene process, which may provide high density interconnects (e.g., damascene interconnects).

It should be noted that the sequence of FIGS. 10A-10B may combine one or more stages in order to simplify and/or clarify the sequence for providing or fabricating a metallization portion. In some implementations, the order of the processes may be changed or modified. In some implementations, one or more of processes may be replaced or substituted without departing from the scope of the disclosure.
Stage 1, as shown in FIG. 10A, illustrates a state after a dielectric layer 1000, a liner layer 1002, an interconnect 1004, a coating layer 1006, a dielectric layer 1008, a coating layer 1010, a photo resist layer 1020, and an opening 1012 are provided and formed. The dielectric layer 1000 and/or the dielectric layer 1008 may include SiCOH (e.g., Si, C, O and H). The coating layer 1006 may include silicon carbon nitride (SiCN). The coating layer 1006 may help protect the interconnect 1004 from oxidation. The coating layer 1010 may include silicon oxide (e.g., silicon dioxide). The liner layer 1002 may include a barrier layer (e.g., TaN/Ta). The liner layer 1002 may help prevent metal from the interconnect 1004 from diffusing into the dielectric layer 1000. Stage 1 illustrates the opening 1012 being formed through the coating layer 1010, the dielectric layer 1008 and/or the coating layer 1006.
Stage 2 illustrates a state after (i) the photo resist layer 1020 is removed, and (ii) an anti-reflection coating layer 1030 is formed, and another photo resist layer 1040 is formed. The anti-reflection coating layer 1030 is formed in the opening 1012 and over the coating layer 1010. The photo resist layer 1040 is formed over portions of the anti-reflection coating layer 1030.
Stage 3 illustrates a state after portions of the anti-reflection coating layer 1030 are removed. Stage 3 also illustrates a state after an opening 1018 is formed in the dielectric layer 1008.
Stage 4, as shown in FIG. 10B, illustrates a state after a liner layer 1050 and a seed layer 1060 are formed. The liner layer 1050 may include a barrier layer (e.g., TaN/Ta). The seed layer 1060 is formed over the liner layer 1050. The seed layer 1060 may include copper. A deposition process may be used to form the liner layer 1050. A deposition process may be used to form the seed layer 1060.
Stage 5 illustrates a state after an interconnect 1070 is formed. The interconnect 1070 may include copper. The interconnect 1070 may be coupled to the seed layer 1060. A plating process may be used to form the interconnect 1070.
Stage 6 illustrates a state after the interconnect 1070 is planarized and a coating layer 1080 is formed over the interconnect 1070 and the dielectric layer 1008. The coating layer 1080 may include silicon carbon nitride (SiCN). The process of stages 1 through 6 may be iteratively repeated to form additional dielectric layers and/or additional interconnects.

It is noted that the liner layer 1050 may considered part of the interconnect 1070. Thus, in some implementations, a liner layer that is touching an interconnect may be considered part of the interconnect. Similarly, a seed layer that is touching an interconnect may be considered part of the interconnect.

It is noted that any of the electrically conductive material may be considered part of an interconnect. Thus, an electrically conductive material that touches the interconnect may be considered part of the interconnect. For example, the seed layer 1060 may be considered part of the interconnect 1070. The plurality of interconnects that are formed using the above process may have a minimum pitch of about 25 nanometers (nm). In some implementations, interconnects may have thickness in a range of about 20 nanometers-5 micrometers. In some implementations, a dielectric may have a thickness in a range of about 20 nanometers-5 micrometers. For example, a dielectric layer between two adjacent metal layers of the plurality of interconnects may have a thickness in a range of about 20 nanometers-5 micrometers.

Thus, a metallization portion that is fabricated using the above damascene process may have interconnects with a minimum pitch of about 25 nanometers (nm).

### Exemplary Electronic Devices

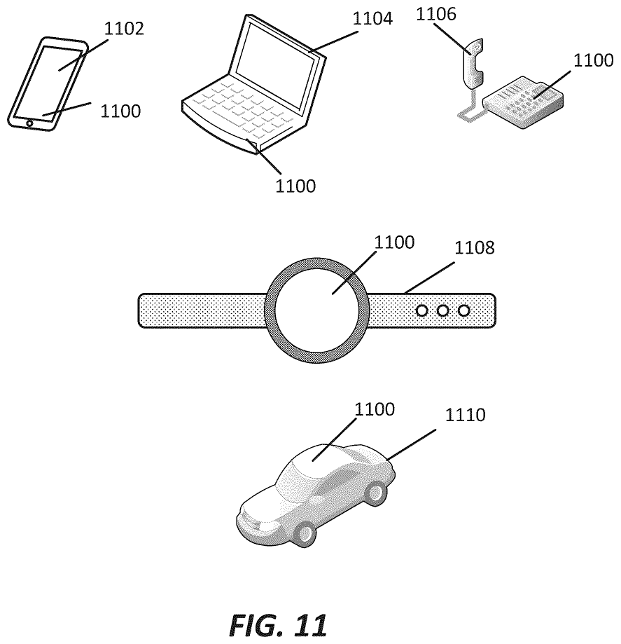

FIG. 11 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 1102, a laptop computer device 1104, a fixed location terminal device 1106, a wearable device 1108, or automotive vehicle 1110 may include a device 1100 as described herein. The device 1100 may be, for example, any of the devices and/or integrated circuit (IC) packages described herein. The devices 1102, 1104, 1106 and 1108 and the vehicle 1110 illustrated in FIG. 11 are merely exemplary. Other electronic devices may also feature the device 1100 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-4, 5A-5C, 6, 7A-7C, 8-9, 10A-10B and 11 may be rearranged and/or combined into a single component, process, feature or function or embodied in several components, processes, or functions. Additional elements, components, processes, and/or functions may also be added without departing from the disclosure. It should also be noted FIGS. 1-4, 5A-5C, 6, 7A-7C, 8-9, 10A-10B and 11 and its corresponding description in the present disclosure is not limited to dies and/or ICs. In some implementations, FIGS. 1-4, 5A-5C, 6, 7A-7C, 8-9, 10A-10B and 11 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.
Aspect 1: A package comprising a base substrate; a first integrated device coupled to the base substrate through a bonding material; a second integrated device coupled to the base substrate through the bonding material; a fill material coupled to the base substrate, the first integrated device and the second integrated device; and a metallization portion coupled to the first integrated device and the second integrated device.
Aspect 2: The package of aspect 1, wherein the bonding material comprises a first bonding material and a second bonding material, wherein the first integrated device comprises a first back side that is coupled to and touching the first bonding material, and wherein the second integrated device comprises a second back side that is coupled to and touching the second bonding material.
Aspect 3: The package of aspects 1 through 2, wherein the fill material is coupled to and touching the first integrated device, the second integrated device and the base substrate.
Aspect 4: The package of aspects 1 through 3, wherein the metallization portion comprises at least one passive device.
Aspect 5: The package of aspect 4, wherein the at least one passive device comprises a capacitor and/or an inductor.
Aspect 6: The package of aspects 1 through 5, further comprising a plurality of pillar interconnects coupled to the metallization portion.
Aspect 7: The package of aspects 1 through 6, wherein the metallization portion comprises at least one dielectric layer; and a plurality of metallization interconnects.
Aspect 8: The package of aspect 7, wherein the plurality of metallization interconnects comprise a plurality of damascene interconnects.
Aspect 9: The package of aspects 7 through 8, wherein the plurality of metallization interconnects comprises interconnects with width and spacing that are less than 1 micron.
Aspect 10: The package of aspects 1 through 9, wherein the base substrate includes at least one cavity, wherein the fill material comprises a first inorganic material, and wherein the bonding material comprises a second inorganic material.
Aspect 11: The package of aspects 1 through 10, wherein the base substrate comprises silicon, wherein the fill material comprises silicon oxide, and wherein the bonding material comprises oxide or silicon.
Aspect 12: A method for fabricating a package. The method provides a base substrate. The method couples a first integrated device to the base substrate through a bonding material. The method couples a second integrated device to the base substrate through the bonding material. The method couples a fill material to the base substrate, the first integrated device and the second integrated device. The method couples a metallization portion to the first integrated device and the second integrated device.
Aspect 13: The method of aspect 12, wherein the first integrated device comprises a first back side that is coupled to and touching the bonding material, and wherein the second integrated device comprises a second back side that is coupled to and touching the bonding material.
Aspect 14: The method of aspects 12 through 13, wherein the fill material is coupled to and touching the first integrated device, the second integrated device and the base substrate.
Aspect 15: The method of aspects 12 through 14, wherein the metallization portion comprises at least one passive device.
Aspect 16: The method of aspects 12 through 15, wherein the metallization portion comprises at least one dielectric layer; and a plurality of metallization interconnects.
Aspect 17: The method of aspect 16, wherein the plurality of metallization interconnects comprise a plurality of damascene interconnects.
Aspect 18: The method of aspects 16 through 17, wherein the plurality of metallization interconnects comprises interconnects with width and spacing that are less than 1 micron.
Aspect 19: The method of aspects 12 through 18, wherein the base substrate includes at least one cavity.
Aspect 20: The method of aspects 12 through 19, wherein the base substrate comprises silicon, wherein the fill material comprises silicon oxide, and wherein the bonding material comprises oxide or silicon.
Aspect 21: The package of aspects 1 through 11, wherein the package is implemented in a device that is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a base substrate;
a first integrated device coupled to the base substrate through a bonding material;
a second integrated device coupled to the base substrate through the bonding material;
a fill material coupled to the base substrate, the first integrated device and the second integrated device; and
a metallization portion coupled to the first integrated device and the second integrated device.

2. The package of claim 1,
wherein the bonding material comprises a first bonding material and a second bonding material,
wherein the first integrated device comprises a first back side that is coupled to and touching the first bonding material, and
wherein the second integrated device comprises a second back side that is coupled to and touching the second bonding material.

3. The package of claim 1, wherein the fill material is coupled to and touching the first integrated device, the second integrated device and the base substrate.

4. The package of claim 1, wherein the metallization portion comprises at least one passive device.

5. The package of claim 4, wherein the at least one passive device comprises a capacitor and/or an inductor.

6. The package of claim 1, further comprising a plurality of pillar interconnects coupled to the metallization portion.

7. The package of claim 1, wherein the metallization portion comprises:
at least one dielectric layer; and
a plurality of metallization interconnects.

8. The package of claim 7, wherein the plurality of metallization interconnects comprise a plurality of damascene interconnects.

9. The package of claim 7, wherein the plurality of metallization interconnects comprises interconnects with width and/or spacing that are less than 1 micron.

10. The package of claim 1,
wherein the base substrate includes at least one cavity,
wherein the fill material comprises a first inorganic material, and
wherein the bonding material comprises a second inorganic material.

11. The package of claim 1,
wherein the base substrate comprises silicon,
wherein the fill material comprises silicon oxide, and
wherein the bonding material comprises oxide or silicon.

12. A method for fabricating a package, comprising:
providing a base substrate;
coupling a first integrated device to the base substrate through a bonding material;
coupling a second integrated device to the base substrate through the bonding material;
coupling a fill material to the base substrate, the first integrated device and the second integrated device; and
coupling a metallization portion to the first integrated device and the second integrated device.

13. The method of claim 12,
wherein the first integrated device comprises a first back side that is coupled to and touching the bonding material, and
wherein the second integrated device comprises a second back side that is coupled to and touching the bonding material.

14. The method of claim 12, wherein the fill material is coupled to and touching the first integrated device, the second integrated device and the base substrate.

15. The method of claim 12, wherein the metallization portion comprises at least one passive device.

16. The method of claim 12, wherein the metallization portion comprises:
at least one dielectric layer; and
a plurality of metallization interconnects.

17. The method of claim 16, wherein the plurality of metallization interconnects comprise a plurality of damascene interconnects.

18. The method of claim 16, wherein the plurality of metallization interconnects comprises interconnects with width and spacing that are less than 1 micron.

19. The method of claim 12, wherein the base substrate includes at least one cavity.

20. The method of claim 12,
wherein the base substrate comprises silicon,
wherein the fill material comprises silicon oxide, and
wherein the bonding material comprises oxide or silicon.
